(19) United States
(12) Patent Application Publication
(10) Pub. No.: US 2010/0224236 A1
(43) Pub. Date: Sep. 9, 2010

(54) Nanohole Film Electrodes

(75) Inventors: Thomas H. Reilly, III, Golden, CO (US); Jao van de Lagemaat, Golden, CO (US); Robert C. Tenent, Golden, CO (US)

Correspondence Address: PAUL J WHITE, Assoc. General Counsel;NATIONAL RENEWABLE ENERGY LABORATORY (NREL), 1617 COLE BOULEVARD, MS 1734, GOLDEN, CO, 80401-3393, US

(73) Assignee: Alliance for Sustainable Energy, LLC, Golden, CO (US)

(21) Appl. No.: 12/397,172

(22) Filed: Mar. 3, 2009

(51) Int. Cl. H01L 31/00; H01R 43/16; G01N 21/55; G01N 21/59

(52) U.S. Cl. 136/255; 136/256; 29/874; 29/885; 356/448; 356/433

(57) ABSTRACT

Nanohole electrodes useful in opto-electronic devices, and in particular, organic photovoltaics devices incorporating nanohole electrodes, are disclosed. An exemplary embodiment includes a photovoltaic device with a first electrode comprising a nanohole film, a second electrode, and an active layer located between the electrodes. Methods of producing a nanostructured electrode are also provided.

The United States Government has rights in this invention under Contract No. DE-AC36-08GO28308 between the United States Department of Energy and the Alliance for Sustainable Energy, LLC, manager and operator of the National Renewable Energy Laboratory.

### BACKGROUND

Photovoltaic devices with an active layer consisting of organic materials have the potential to fulfill the promise of economical electrical power generation from the sun. These so-called “organic photovoltaics” (OPV) are a promising low-cost alternative to conventional photovoltaic technologies. A persistent challenge with OPV devices has been the thickness of the light-absorbing layer, which must allow for light absorption in the active layer while also permitting the photogenerated carriers to reach the charge collecting electrodes before recombination.

Because of the poor charge carrier mobility of typical OPV active layers, optically thin films are required in order to reduce recombination losses. Many OPV devices employ front electrodes made of materials such as indium tin oxide (ITO). However, indium is a scarce resource with alternative uses in the flat panel display industry, which has made the long-term availability and cost unreliable. Indium has also been shown to migrate out of the ITO layer into surrounding organic optoelectronic layers, reducing performance.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

Exemplary embodiments provide photovoltaic devices comprising a first electrode comprising a nanohole film, a second electrode, and an active layer located between the electrodes.

In some embodiments, the active layer comprises poly-3-hexylthiophene (P3HT) and phenyl-C61-butyric-acid-methyl ester (PCBM) as a bulk heterojunction active layer. In certain embodiments, the photovoltaic device further comprises a buffer layer comprising a poly(3,4-ethylenedioxythiophene) (PEDOT)-type polymer.

In specific embodiments, the nanohole film is a metal film with subwavelength apertures, such as a silver film with subwavelength apertures that are less than 300 nm.

In some embodiments, the fractional coverage of the nanoholes across the electrode surface is less than 0.3.

Exemplary embodiments also provide methods of producing a nanostructured electrode comprising treating a substrate with at least one polyelectrolyte, depositing spheres on the treated substrate, depositing a metal (for example, silver) film on the substrate, and removing the spheres from the metal film-coated substrate.

In specific embodiments, the method further comprises a step of washing the substrate prior to depositing the metal film or a step of heating the substrate to reduce aggregation of the spheres.

In some embodiments, the spheres are deposited on the substrate by contacting the substrate with a solution comprising spheres and a salt.

In specific embodiments, the method further comprises a step of altering the salt concentration of the solution comprising the spheres and the salt to change the density of spheres deposited on the substrate. In certain embodiments, the spheres are charged. In additional embodiments, the spheres are removed by sonicating the metal film-coated substrate.

Exemplary embodiments also provide methods for determining the optical characteristics of at least one nanohole electrode comprising producing at least one nanohole electrode, determining at least one of the transmission or reflection spectrum of the at least one nanohole electrode, and comparing the determined transmission or reflection spectrum with the transmission or reflection spectrum of a reference nanohole electrode.

In specific embodiments, the at least one nanohole electrode comprises a different nanohole aperture size and/or a different nanohole surface coverage than the reference nanohole electrode.

Exemplary embodiments further provide multijunction solar cells comprising more than one electromagnetic radiation absorbing layers and one or more nanohole films between the electromagnetic radiation absorbing layers.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 shows an atomic force micrograph of 30-nm silver nanohole film fabricated by the colloidal lithography method using 350-nm latex spheres.

FIG. 2 shows nanohole coverage as a function of salt concentration in deposition solution. A sigmoidal fit has been added to guide the eye.

FIGS. 3A and 3B show nanohole coverage as a function of particle concentration (A) and deposition time (B).

FIG. 4 shows sheet resistance of nanohole films as a function of fractional hole coverage. The dotted line represents a fit to standard percolation theory indicating the electrical properties of the silver films are well described by bulk properties and geometric analysis.

FIGS. 5A and 5B show transmission spectra (A) and reflectance spectra (B) measured with an integrating sphere for a series of nanohole silver films with varying nanohole coverage. The spectra demonstrate that the magnitude of transmission or reflectance can be tuned via nanohole coverage without changing the nanohole size. The inset legend indicates the nanohole coverage for each spectrum.

FIG. 6 shows calculated absorbance spectra of the nanohole films as a function of nanohole coverage. With increasing nanohole coverage, the films are capable of trapping more light at the surface.

FIGS. 7A and 7B show calculated extinction spectra of a nanohole film based on direct transmission and reflection measurements. The legends indicate the angle between excitation and collection optics for the film. P-polarized extinction spectra of a nanohole film (A) and S-polarized extinction spectra from the same film (B) are shown.

FIG. 8 shows integrated transmission spectra (in eV) of the silver nanohole films as a function of nanohole coverage. The data have been normalized to the integrated value of the silver reference film. On this scale, 100% integrated transmission produces a value of 9.09.

FIG. 9 shows direct transmission spectra collected for 30 nm thick silver films where 60 nm diameter latex spheres were used to compose the mask. The silver was deposited at an angle such that rather than a circular hole being created by the relief structure an asymmetric nanohole was created. For reference, a symmetric nanohole film (100 nm) was also investigated at different light polarizations.

FIG. 10 shows direct transmission spectra from 200 nm diameter nanoholes deposited in the same asymmetric way as for the 60 nm holes from FIG. 9. These asymmetric nanoholes also show different transmission spectra under different polarization illumination.

FIG. 11 shows transmission spectra of the different front electrode materials with a 30-nm poly(3,4-ethylenedioxythiophene):poly(styrenesulfonate) (PEDOT:PSS) film. The transmission spectra were recorded using an integrating sphere to capture directly transmitted light and forward scattered light. The samples were illuminated through the glass substrate to mimic the same illumination geometry as the test cell evaluation conditions.

FIG. 12 shows the incident photon-to-current conversion efficiency (IPCE) spectra of the OPV cells divided by the far-field transmission spectra of the front electrodes with PEDOT:PSS film. IPCE spectra were measured using a home built instrument that was calibrated using a certified silicon photodiode.

### DETAILED DESCRIPTION

Electrodes for use in opto-electronic devices and methods of producing and using the electrodes are provided herein. In some aspects, the electrodes are used in organic photovoltaic (OPV) devices. The devices and methods described herein provide a significant advantage in that the electrodes are fabricated from relatively common materials, rather than scarce and expensive elements such as indium.

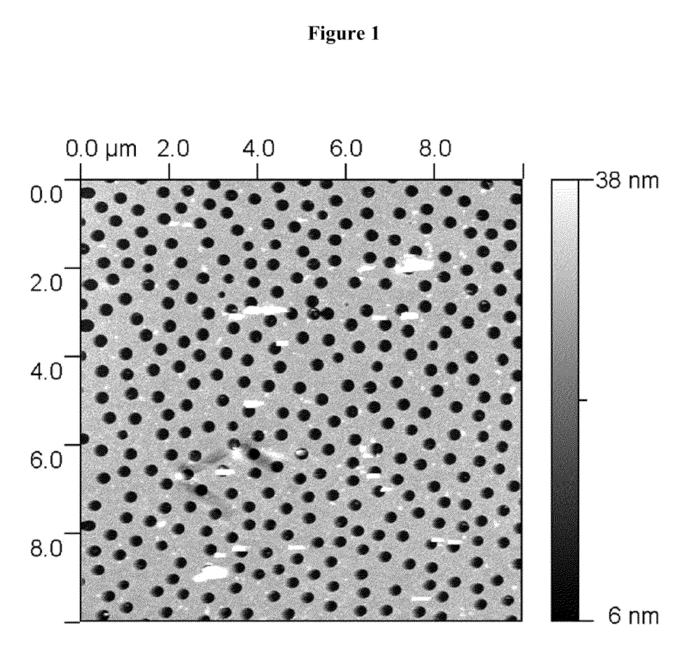

The electrodes disclosed herein comprise surface plasmon (SP) active films. SPs are excitations of the free electrons on the surface of metals that can be generated by light. Suitable SP-active films for use in the electrodes exhibit high optical transmission and low sheet resistance. In one aspect, a SP-active system with the potential to satisfy both of the electrode requirements is a nanohole array in a thin metal film. Nanoscale perforations may render opaque metal films semi-transparent, thereby enhancing optical transmission. FIG. 1 shows an example of a nanohole array (350 nm holes) in a 30 nm silver film.

Opaque metal films can be made partially transparent by perforating the films with subwavelength apertures at submonolayer coverages. As light exits the nanoaperture array, the electric field intensity is maximized near the perimeter of the aperture, which may lead to a direct increase in absorption by materials in close proximity to the surface. Without being bound by any theory, it is believed that nanohole coverage, rather than periodicity, results in the increased magnitude of transmitted light through these films. The methods disclosed herein allow for the production of large area arrays of disordered nanohole films, which may be used in opto-electronic devices such as OPV cells.

Metals suitable for use in the electrodes include calcium, aluminum, iron, platinum, palladium, copper, lithium, sodium, potassium, magnesium, cesium, silver, gold, nickel and possibly alloys thereof. In addition to metals, the electrodes may comprise semiconductors that at some wavelengths have a real dielectric value that is negative (e.g., silicon in the terahertz region). In certain embodiments, the metal may be silver.

The nanoholes are typically round in shape due to the use of spheres in the colloidal lithography process used to generate the films. However, the nanoholes may be additional shapes, including oval, square or irregularly shaped. The materials used in the colloidal lithography manufacturing process may be varied to create nanoholes of distinct shapes and sizes.

Likewise, the size (i.e., diameter) of the nanoholes may be varied by using spheres or other particles of varying size in the lithography process. The apertures may be of any size smaller than the wavelength of the incident electromagnetic radiation. Varying the size of the nanoholes allows one to customize the resulting transmission and reflection spectra, as discussed in greater detail below.

Examples of aperture sizes suitable for transmission of wavelengths within the visible (i.e., 380-750 nm) and near-infrared (i.e., 750-1400 nm) spectra include 60 nm, 92 nm, 100 nm, 200 nm and 300 nm. One of skill in the art can readily select a subwavelength aperture size to meet the desired transmission and/or reflection profile of the electrode. In certain embodiments, the nanohole apertures may be less than 1000 nm, less than 950 nm, less than 900 nm, less than 850 nm, less than 800 nm, less than 750 nm, less than 700 nm, less than 650 nm, less than 600 nm, less than 550 nm, less than 500 nm, less than 450 nm, less than 400 nm, less than 350 nm, less than 300 nm, less than 250 nm, less than 200 nm, less than 150 nm, less than 125 nm, less than 100 nm, less than 75 nm, less than 50 nm, less than 25 nm, or less than 10 nm.

The electrodes may be of any thickness suitable for use in opto-electronic devices. Typically, optically thin films are required in order to reduce recombination losses while allowing the maximum amount of solar radiation to reach the active layer. Electrodes may be as thin as 10 nm or as thick as several hundred nanometers. One of skill in the art will know to select the appropriate thickness for the specific application of the electrode. Examples of suitable thicknesses include 30 nm and 40 nm. In some embodiments, electrode thickness may be less than 300 nm, 250 nm, 200 nm, 150 nm, less than 100 nm, less than 90 nm, less than 80 nm, less than 70 nm, less than 60 nm, less than 50 nm, less than 40 nm, less than 30 nm, less than 20 nm, or less than 10 nm.

The density of nanoholes on an electrode may be varied using the techniques described below. Deposition time and particle concentration employed in lithography procedures may be varied to alter the ultimate hole density. The fractional coverage of the nanoholes across the surface may be varied from about 0.01 to about 0.4. Varying the fractional coverage also varies the transmission and reflection spectra of the electrode. In certain embodiments, the fractional coverage of the nanoholes across the electrode surface may be less than 0.4, 0.35, 0.3, 0.25, 0.2, 0.15, 0.1, 0.05, or 0.025.

Exemplary embodiments include the incorporation of these electrodes into an opto-electronic device. Examples include OPV devices such as a bulk-heterojunction organic photovoltaic device. In certain embodiments, the electrode may be the front electrode of an OPV cell.

The active layer in OPV devices typically consists of two materials, a p-type (donor or hole conductor) and an n-type (acceptor or electron conductor). In these structures, the absorption of a photon creates an exciton, a bound electron-hole pair. Photons are typically absorbed in the p-type material, which is usually a conducting polymer. The exciton must then be dissociated at an interface between the p-type material and the n-type material. The two materials then transport the respective charges to opposite electrodes, and current flow is measured in the device. The efficiency of the device greatly depends on the “HOMO-LUMO” gap, the energy difference between the highest occupied molecular orbital (HOMO) of the donor and the lowest unoccupied molecular orbital (LUMO) of the acceptor in the active layer from which the bands are formed in the solid state.

The efficiency also depends on providing a lot of interface area for the exciton to dissociate, but not so much that the charges must travel far to get to an electrode. One of the most useful architectures for OPV devices is the bulk heterojunction (BHJ) device, which seeks to maximize the area of interface between the n-type and the p-type material by partially blending the two materials. Phenyl-C61-butyric-acid-methyl ester (PCBM) is often used as the n-type material in this kind of device, due in part to its moderately high electron transport rate. Poly-3-hexylthiophene (P3HT) is often used as a p-type material, in part because its hole mobility leads to better short circuit current density (Jsc) values.

In certain embodiments, the nanohole film electrodes may be incorporated into organic solar cells that comprise P3HT and PCBM as a bulk heterojunction active layer.

OPV devices may also comprise an electron blocking buffer layer, which is typically located between the front electrode and the active layer of the cell. The buffer layer may be included, inter alia, to assist the active layer by wetting the surface; to serve as an effective spacer layer and thereby prevent chemical interactions between the active layer and the front electrode; or to soften the features of the nanoaperture film, leaving shallow depressions on the surface.

The buffer layer may comprise polymers of 3,4-dialkoxythiophene moieties such as PEDOT-type polymers (e.g., MDOT, EDOT, VDOT, Benzo-EDOT, or similar materials). Another suitable polymer is poly(3,4-ethylenedioxythiophene) (PEDOT), which may be in complex with poly(styrenesulfonate) (PEDOT:PSS). Additional suitable materials include small molecules that support similar functions, such bathocuproine (BCP), N,N′-di-1-naphthyl-N,N′-diphenyl-1,1′-biphenyl-4,4′diamine (NPD), or Tris(8-hydroxyquinolinato)aluminium (Alq3).

The second electrode (often called the “back” electrode because it is deposited last) is typically aluminum, LiF/Al, or a low-work function metal such as calcium or barium or combinations or alloys thereof. Any material known in the art for use as a back electrode may be used. Additional examples include conductive metals such as platinum, gold or silver. The second electrode may be thermally deposited or sputtered under high vacuum, or applied by printing, soft contact lamination or other ambient pressure technique, or by any other technique known in the art.

The nanohole films may also be incorporated within multijunction solar cells. For example, one or more nanohole films may be placed between the electromagnetic radiation absorbing layers of a multijunction solar cell. The composition and aperture size of the nanohole film may be selected to maximize the spectrum of electromagnetic radiation transmitted to a lower absorbing layer within the cell and/or to maximize the spectrum of electromagnetic radiation reflected to an upper absorbing layer within the cell.

Nanohole arrays may be generated using colloidal lithography techniques. Controlling the reagent concentrations, ionic strength of deposition solutions used, and assembly times in the colloidal lithography techniques allows the creation of a wide range of nanohole densities within an electrode. The tenability of the colloidal lithography assembly method described below thus allows for the generation of customized transparent electrodes with high surface plasmon activity throughout various spectra (e.g., the visible and NIR spectrum) over large surface areas. In order to further optimize this front electrode system, hole size, hole coverage, metal film thickness, and spacer layer thickness may be tailored to each individual application, while accounting for any interference and/or cavity effects.

In general, the nanohole electrodes may be produced by the following method:

a) treating a substrate with at least one polyelectrolyte;

b) depositing spheres on the treated substrate;

c) depositing a metal film on the substrate; and

d) removing the spheres from the metal film-coated substrate.

The substrate may be a glass slide or any other suitable substrate known in the art. Typically, the substrate is cleaned and dried using standard techniques prior to polyelectrolyte treatment. The substrate may be treated with one or more polyelectrolytes using any conventional treatment method, such as immersing the substrate in one or more polyelectrolyte solutions. The substrate may be rinsed and dried after polyelectrolyte treatment.

Suitable polyelectrolytes include Poly(diallyldimethyl ammonium chloride (PDDA), poly(sodium 4-styrene sulfonate) (PSS), or combinations thereof. In certain embodiments, the substrate is also treated with a small molecule electrolyte such as aluminum chlorohydrate (AlCH). The substrate may be subjected to successive treatments with one or more polyelectrolytes/small molecule electrolyte. In one embodiment, the substrate may be treated sequentially with PDDA, PSS and AlCH. For example, the substrate may be sequentially exposed to 30 second dips in 2% by weight solution of PDDA, 2% PSS and 5% AlCH solutions.

Following polyelectrolyte treatment, spheres may be deposited on the treated substrate. The spheres may be contained within a solution that is placed on the substrate, and the salt concentration of the sphere solution may be varied to alter charge repulsion between spheres, thereby altering the nanohole density of the resulting electrode.

Suitable spheres may be uncharged, but may also be charged to take advantage of charge repulsion effects. Many sources of charged and uncharged spheres are known in the art. Any particle of appropriate size with some degree of tunable surface chemistry may be used. In certain embodiments, the spheres may be latex spheres, polystyrene spheres, nanoparticle oxide spheres (e.g., silicon dioxide (SiO₂) titanium dioxide) or metal nanoparticles (e.g., gold and silver spheres that have treated surfaces). The diameter of the sphere may be selected to match the diameter of the desired nanohole aperture in the resulting electrode.

Optionally, the substrate may be washed or rinsed following sphere deposition to remove excess spheres. For example, the substrate may be rinsed with a spray bottle or immersed in water. The substrate may also be heated (e.g., by immersing in heated water) to reduce aggregation of the spheres. Such a step may be particularly useful where high-density sphere arrays are desired. Substrates may then be cooled (if necessary) and dried.

Following sphere deposition, a metal film may then be deposited on the substrate to the desired electrode thickness (e.g., 30-40 nm). Any film deposition technique known in the art may be used. In one embodiment, the metal film may be deposited in a thermal evaporator at a rate of 1 Å/s starting with a base pressure of 1e-7 Torr.

Following metal film deposition, the spheres may be removed from the metal film coated substrate. In certain embodiments, the films with embedded spheres may be sonicated in isopropanol. However, any removal technique known in the art may be employed. In some embodiments, the films may be sonicated for less than 30 minutes or sonicated multiple times for less than 15 minutes each.

After fabrication, the nanohole electrodes may be used in the construction of opto-electronic, such as (OPV) devices, using conventional techniques known in the art. It is readily appreciated that applications of this technology may include, but are not limited to, PV devices.

Altering the salt concentration of the sphere solution may result in nanohole arrays of varying densities. In one aspect, the colloidal lithography technique utilizes the repulsion between similarly charged spheres to provide spacing and eventual short range order between the spheres when adsorbed on a charged surface. Without the use of an added salt, maximum fractional coverage approaches about 0.20. To obtain higher hole densities, the ionic strength of the deposition solution may be changed by increasing the salt concentration. As salt concentration increases, more of the charge on the spheres becomes shielded, thus allowing control of the distance between spheres.

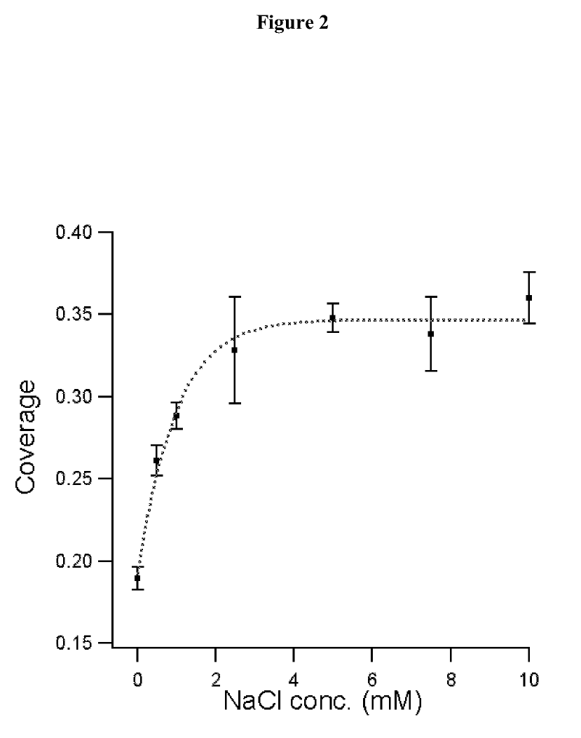

FIG. 2 shows the fractional coverage of 92 nm holes in a 2.5 μm by 2.5 μm surface region as a function of concentration of NaCl added to the deposition solution. The depositions were performed with a 0.1% particle concentration and using a 30 minute deposition time. The hole density increases upon the addition of salt and approaches about 0.35. Each data point shown is an average of particle counts from at least three regions of the surface.

High density samples may be heat treated after the initial sphere deposition to reduce aggregate formation. For higher particle densities, the particles may initially be highly aggregated, but may then redistribute upon heating. In certain embodiments, the samples are heated in a hot bath with the water in the bath at a boil prior to exposing deposited spheres. With the bath at lower temperatures, aggregation of high density may result.

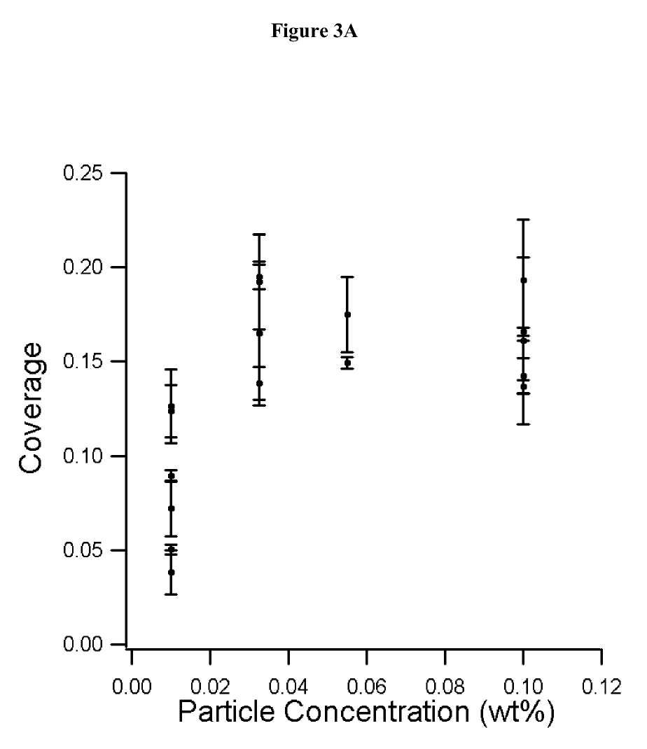

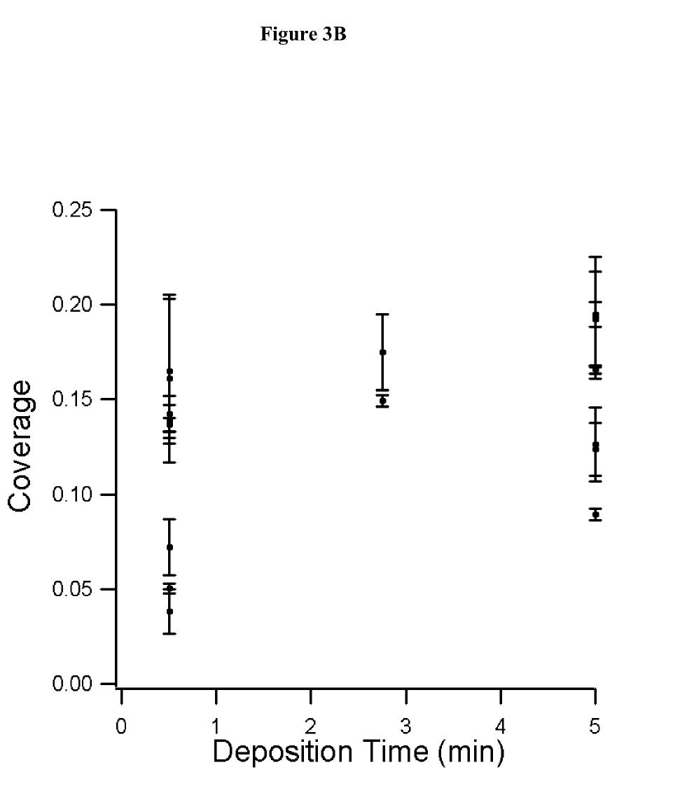

Surface coverages below 0.20 may be obtained by adjusting both the solution particle concentration and the deposition time. FIG. 3 shows fractional surface coverage as a function of (A) deposition time and (B) particle concentration. The linear dependence of coverage on time can be seen for the particle concentrations used. The highest particle concentrations and times used gave a surface coverage similar to those observed for the control experiments at 0.1% particle concentration and 30 minute deposition times. Under these conditions, times in excess of five minutes did not appear to have an appreciable effect on surface coverage.

The same coverage data is plotted as a function of particle concentration in FIG. 3(B). Particle concentrations above 0.0325% resulted in similar surface coverage numbers. The data at the lowest particle concentration give the only statistically significant difference in surface coverage with a minimum coverage observed at 0.01% particle concentration and a deposition time of 30 seconds of 0.04±0.01.

While deposition time does play a role in final surface coverage, particle concentration appears to play a larger role in determining the ultimate hole density. Close to maximum film density may be achieved in under 30 seconds. In one aspect, a practical way to control surface coverage may be by using low concentrations of particles with deposition times of no longer than 5 minutes.

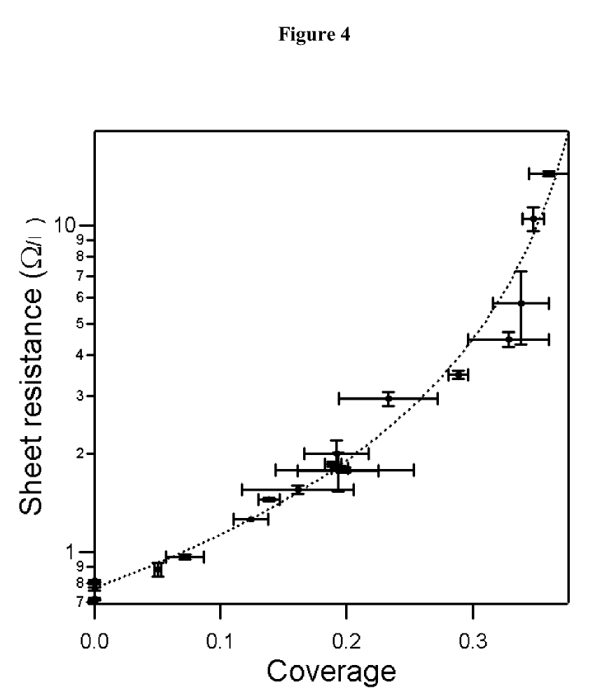

The sheet resistance of electrodes may also be altered by varying the nanohole surface coverage. The sheet resistance of the films as a function of nanohole surface coverage is shown in FIG. 4. The sheet resistance in each nanohole film appears better than that typically reported for indium tin oxide coated glass substrates (a standard transparent electrode). The influence of nanohole coverage on sheet resistance may be determined by the following equation derived from percolation theory:

f(c)=A×(c_{crit}−c)^{η}

where A is a pre-exponential factor, c_{crit} is the critical coverage condition where the probability of a conducting pathway in the film falls to zero, c is the hole coverage, and η is the 2D conductivity exponent. Fitting the conductivity data to the percolation threshold equation yielded a c_{crit} value of 0.42±0.01 and a 2D conductivity exponent of 1.37±0.06. While nanostructuring the surface can have strong non-classical optical effects, the conductivity of the silver films as a function of hole coverage still appears to follow a percolation threshold theory. The sheet resistance values observed here suggest these films have promising high current applications where the resistive losses of typical transparent conductors may result in poor performance.

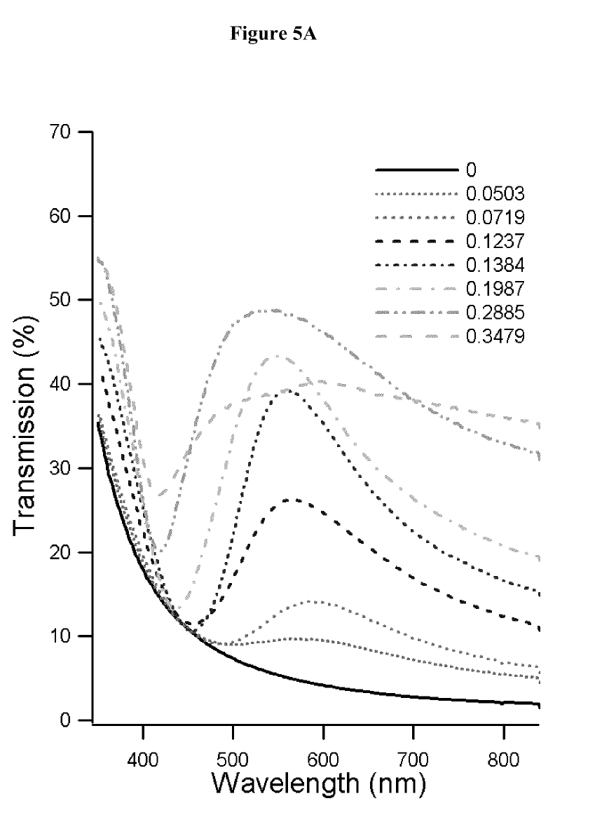

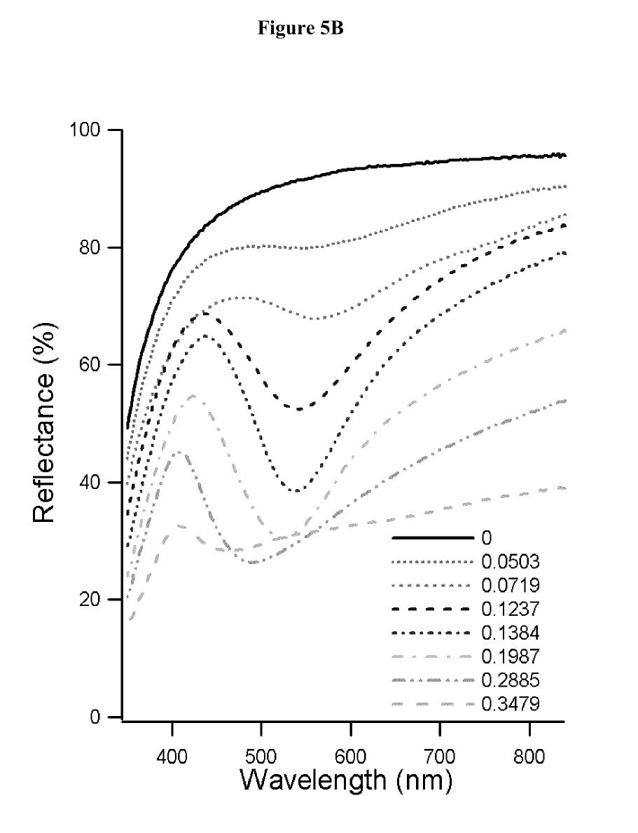

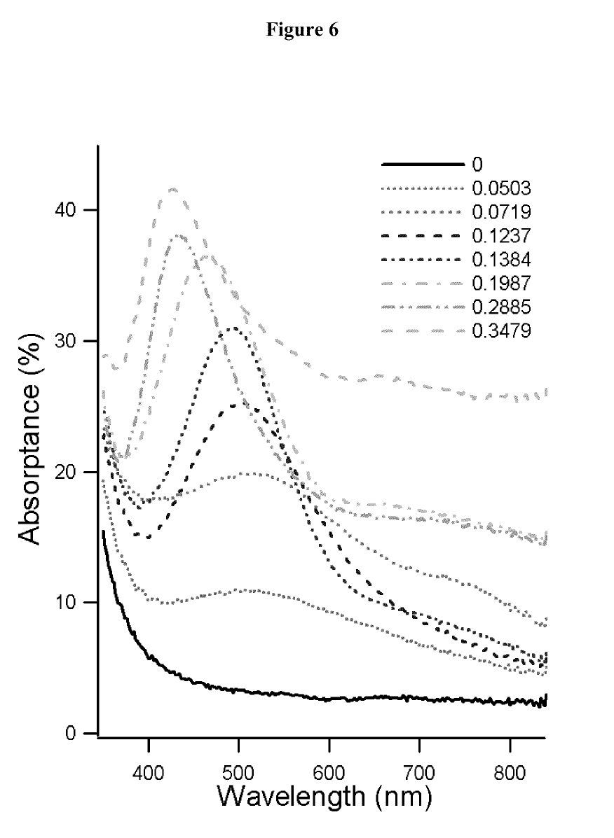

The optical properties of an electrode may be changed by varying the nanohole coverage. FIG. 5 demonstrates the gradual increase and blue shift of the transmission maximum of the nanohole films as a function of hole coverage. The same trend was also observed in the reflection data as the local minimum blue shifted as coverage increased. The percent absorbance of the nanohole films is featured in FIG. 6. Since an integrating sphere was used to capture forward and backscattered light in the transmission and reflection data, the absorbance spectra (A=100−% T−% R) of the nanohole films indicates what percentage of light was trapped by the different films. This is in contrast to the extinction spectra typically reported in the plasmonics literature, which do not distinguish between scattered and absorbed photons.

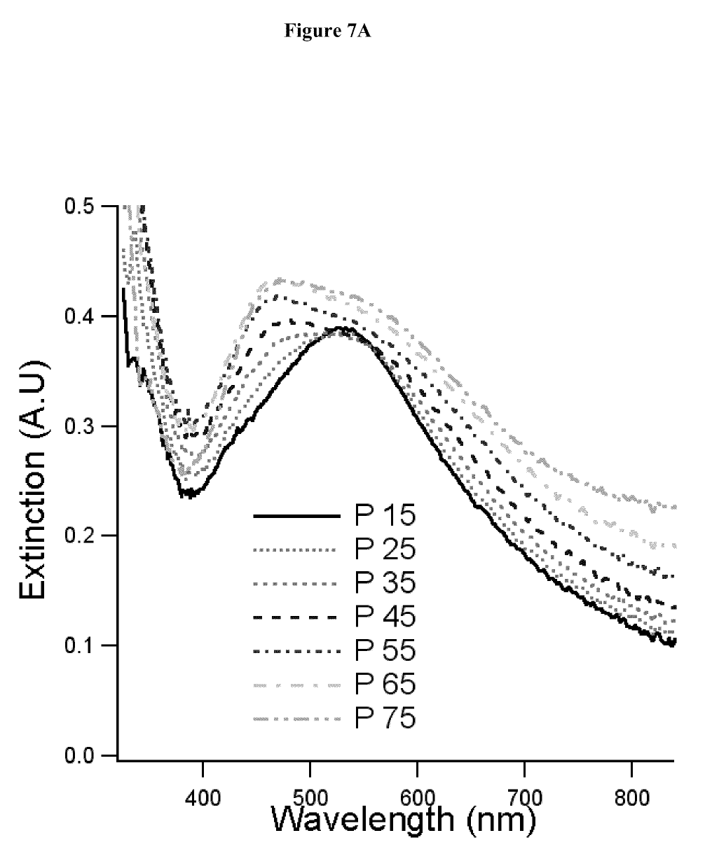

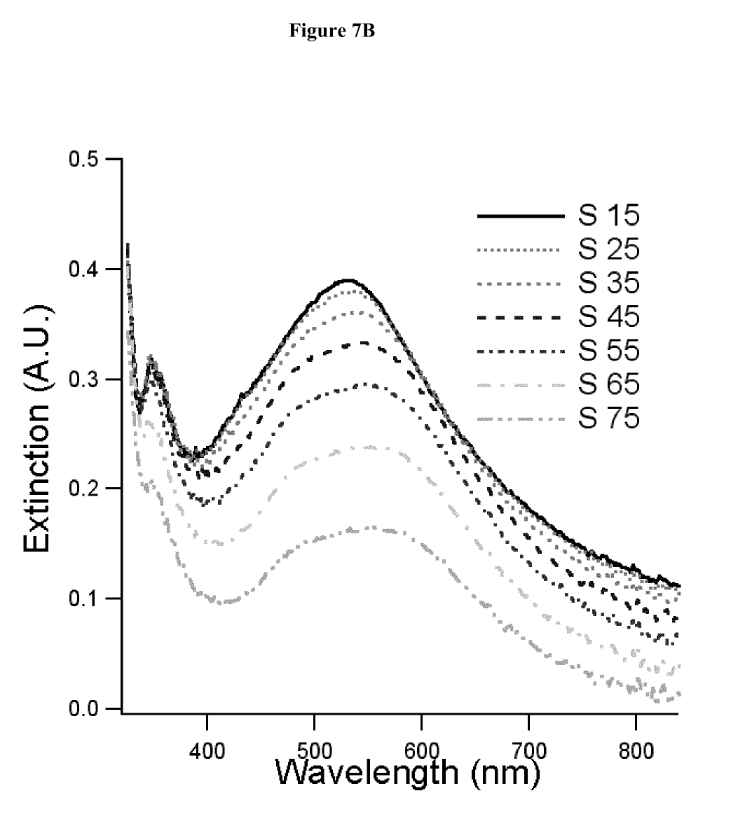

FIG. 7 shows polarization resolved angle dependent extinction spectra of a nanohole film. Extinction was calculated from direct transmission and reflection measurements. As the angle of incidence increases, the extinction of p-polarized light shifts to higher energies. The main extinction feature appears to be composed of two closely overlapping peaks and the relative intensity of the high-energy peak to the low energy peak increases as a function of angle of excitation. The s-polarized extinction spectra flatten and red shift slightly. As the excitation angle increases, the electric field vector of the p-polarized light moves toward a perpendicular excitation of the film instead of a horizontal excitation. A perpendicular excitation should be constrained by the film thickness and the dimensions of the nanohole. Given these two criteria, the high-energy peak in the extinction spectra may be the result of the nanohole cavity localized surface plasmon mode.

Enhanced optical transmission has been defined as the transmitted power incident on the area of a sub-wavelength hole in an optically thick metal film. When the transmitted power through the hole exceeds that predicted by Bethe theory, the transmission is enhanced. For example, at a nanohole coverage of 0.2, the wavelength-integrated transmission does increase from a value normalized to 1 for a silver reference film to a value of about 3, an apparent transmission enhancement of about 15. The hole size, metal used and film thickness can be varied to change the transmission enhancement magnitude.

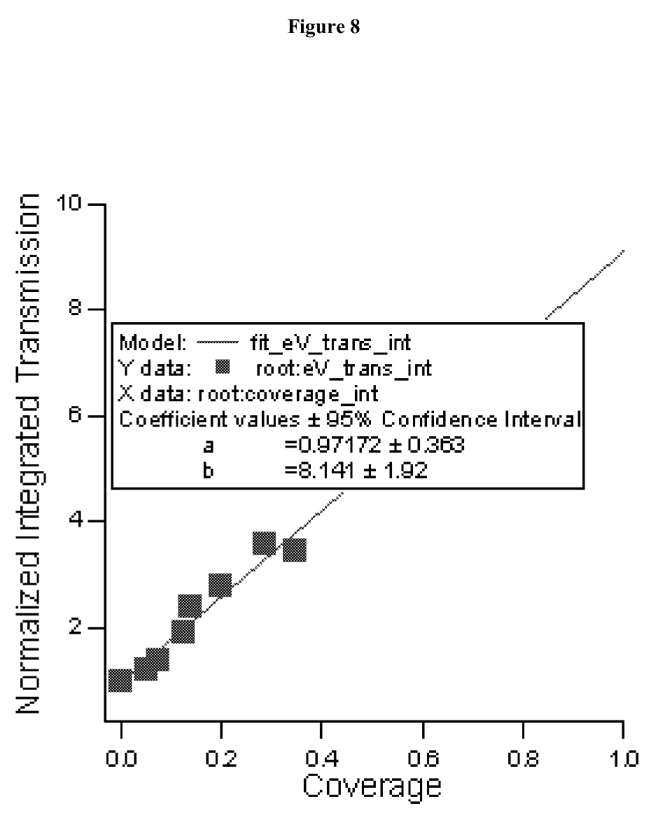

By integrating the nanohole transmission spectra at systematically varied coverages, the values fall on a straight line that starts at the silver reference and extrapolates to within error of the integrated transmission spectra of a blank glass slide. This extrapolation is featured in FIG. 8. While sub-wavelength holes in the metal films do change transmission at specific wavelengths, the process appears to be equally constructive and destructive with respect to light transmission.

Without being bound by any particular theory, it is believed that the reflection and transmission spectra of the nanohole films indicate that the increase in absorbance of the films is due to a loss of reflected power with little loss in forward transmitted light.

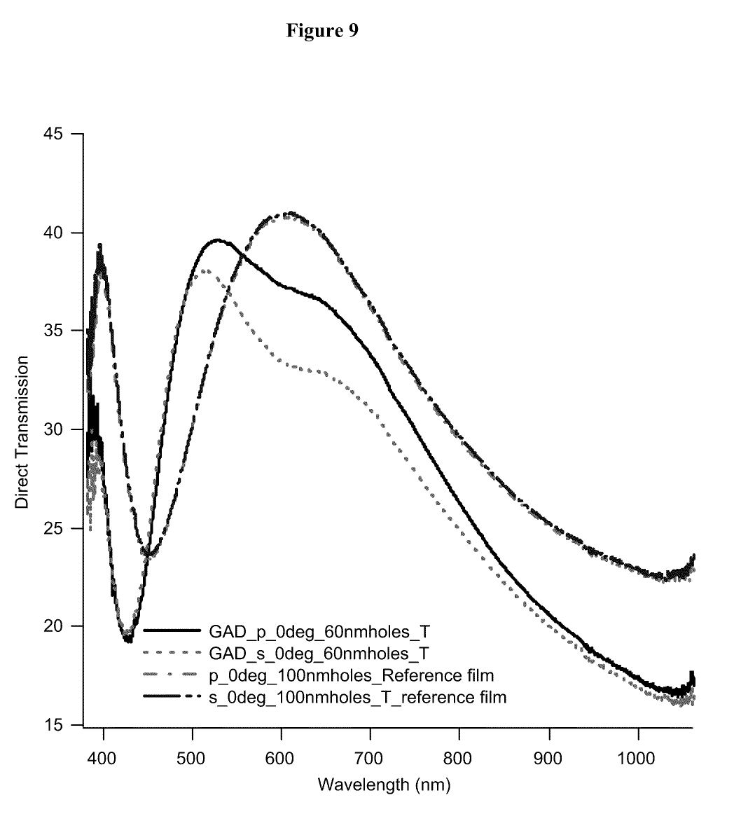

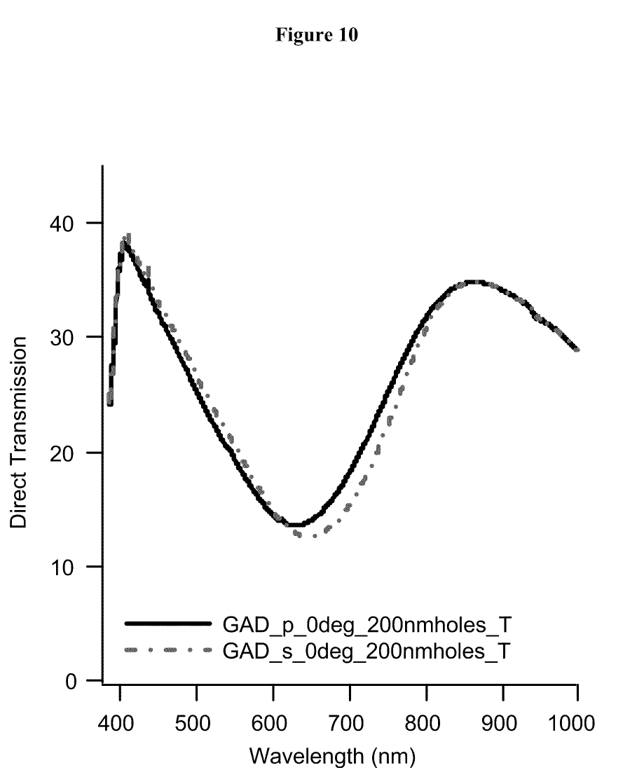

In some aspects, the electrodes may comprise asymmetric nanoholes (i.e., as opposed to circular nanoholes). This may be accomplished, for example, by depositing a metal at an angle rather than directly. Electrodes with asymmetric nanoholes may exhibit distinct transmission spectra as compared to electrodes with circular nanoholes. Examples are shown in FIGS. 9 and 10.

In FIG. 9, direct transmission spectra were collected for 30 nm thick silver films where 60 nm diameter latex spheres were used to compose the mask. The silver was deposited at an angle such that rather than a circular hole being created by the relief structure an asymmetric nanohole was created. The asymmetry of the nanoholes creates a film that has varying transmission spectra depending on what polarization of light is transmitted through the film. This effect is demonstrated in spectra ‘GAD_p_{—}0deg_{—}60nm holes_T’ and ‘GAD_s_{—}0deg_{—}60nm holes_T’, where different polarizations of light were passed through the same film at the same location but demonstrated different transmission. For reference, a symmetric nanohole film was also investigated at different light polarizations and the spectra do not appear to exhibit this effect.

FIG. 10 shows the same effect using larger holes (200 nm diameter). The assymetric nanohole effect where the transmission spectra changes depending on incident polarization is also observed.

The methods described above also allow for the production of customized transparent electrodes with high surface plasmon activity throughout a selected electromagnetic spectrum. This may be accomplished by varying the hole size, hole coverage, metal film thickness, or spacer layer thickness for a given electrode (for example, by controlling the reagent concentrations, ionic strength of deposition solutions used, assembly times, and other parameters in the colloidal lithography techniques).

The optical characteristics of the nanohole electrodes produced with distinct properties (aperture size, nanohole coverage, etc.) may then be compared with a reference nanohole electrode to determine the effect of the varied property. For example, the transmission or reflection spectrum of an altered nanohole electrode may be compared with the transmission or reflection spectrum of a reference nanohole electrode.

### EXAMPLES

### Example 1

Materials. The following materials and solutions were used in subsequent examples.

Sulfate modified latex spheres (92 nm diameter) in water (8% w/v) were purchased from Invitrogen Corporation, Carlsbad, Calif. Poly(diallyldimethyl ammonium chloride (PDDA) (medium molecular weight) 20% in water and poly(sodium 4-styrene sulfonate) (PSS) 30 wt. % solution in water were purchased from Aldrich Chemical Company, St. Louis, Mo. Aluminum chlorohydrate was purchased from Spectrum Chemical Manufacturing Corporation, Gardena, Calif. Sodium Chloride Baker Analyzed Reagent Grade was purchased from J.T. Baker Chemical Company, Phillipsburg N.J. All chemicals were used as received without any further purification.

All solutions were made using 18.2 MΩ deionized water. All salt containing solutions were prepared from dilutions of the same stock solution and were brought to the desired concentration prior to the addition of spheres.

### Example 2

Glass Substrate Cleaning and Polyelectrolyte Treatment. All samples were prepared on glass microscope slides. Slides were scrubbed using a sponge with a dilute solution of Liquinox™ cleaner followed by rinses in tap water, house deionized water, and a final rinse with 18.2 MΩ deionized water. The slides were blown dry using nitrogen. Following the water-based cleaning, slides were treated in an oxygen plasma (700 mTorr O₂, 150 W, 5 minute process time). All depositions were performed within a few hours of, or immediately following, the sample cleaning steps. Prior to exposure to the oxygen plasma clean, the glass slides were cut into roughly 1″ by 1″ squares. Samples were blown off with a nitrogen gun to remove any glass shards remaining from the scribing and breaking process.

The glass surface was modified with a polyelectrolyte multilayer prior to sphere deposition. Slides were exposed to 30 second dips in 2% by weight solution of PDDA, 2% PSS and 5% AlCH solutions sequentially. Samples were rinsed in an 18.2 MΩ water bath and blown dry with nitrogen following each exposure.

### Example 3

Controlled Sphere Deposition. A 0.5 mL aliquot of latex sphere solution was deposited on top of each 1″×1″ square of triple-layer treated glass slide. Samples were left in a closed Petri dish to avoid contamination and avoid solvent loss due to evaporation.

Dense packing of latex spheres was achieved by adding various concentrations of NaCl to the deposition solutions, thereby reducing charge repulsion between spheres. All high coverage samples were deposited for 30 minutes.

Low coverage samples were generated in the absence of intentionally added salts and were controlled by varying both sphere concentration and deposition time.

### Example 4

Post-Deposition Processing. Following the sphere deposition step, samples were rinsed with 18.2 MΩ deionized water. The water meniscus was maintained over the top of the sample to obtain bulk sample uniformity. Samples were maintained level during the rinsing step and rinse water was added with a spray bottle. A gentle stream from the spray bottle was directed away from the center of the sample and to an area that was deemed non-critical to sample success. It was found that a direct sharp stream from the spray bottle could easily remove spheres from the sample surface. Water was streamed over the top of the sample until the meniscus was clear and appeared void of latex spheres.

An alternate method to the gentle rinsing step using a spray bottle is to immerse the entire sample in a beaker of water to remove the excess spheres. For 1″×1″ glass substrates, approximately 400 mL of 18.2 MΩ water was used as the rinse bath at room temperature. Provided a water meniscus remains over the surface of the sample through the entire process, this was determined to be an equally effective means of rinsing the excess sphere suspension. While still carefully maintaining a level surface to keep the meniscus intact, the rinsed sample was immersed in a beaker of boiling water for 60 seconds.

The temperature of the heated bath was found to suppress large-scale aggregation of the spheres on the sample surface. When treated in a hot bath that was at a rolling boil, no large-scale aggregation was observed. If the hot bath was not at a rolling boil, significant aggregation was observed.

After the hot bath soak, samples were transferred into a cold bath, again with great care to maintain the meniscus over the sample surface. The exact temperature of the cold bath was not determined and probably varied during the preparation of large numbers of samples. Initially the cold bath was cooled to the point of containing several ice crystals. No attempt was made to control the temperature of the cold bath and the variability did not appear to have any significant effect on sphere deposition results.

After exposure to the cold bath, samples were transferred, again with careful attention to maintaining the sample level, onto a dry clean Kimwipe™ laboratory wiper, which allowed a large portion of the overlying meniscus to wick away. The sample was then blown dry with nitrogen. A gentle stream of nitrogen was at first focused on the center of the sample, allowing this region to dry first. The flow rate of the nitrogen stream was gradually increased to push the water front out toward the extreme edges of the sample surface. This was done to keep any portion of the dried surface from rewetting. Rewetting of the already dried surface was found to lead to large-scale surface non-uniformity.

### Example 5

Silver Film Deposition and Sphere Removal. Following the sphere deposition steps, silver was deposited at a rate of 1 Å/s starting with a base pressure of 1e-7 Torr in a thermal evaporator (Ångstrom Engineering). In this study, the silver film thickness was kept constant at 40 nm.

Following silver deposition, the silver films with embedded spheres were sonicated in isopropanol. Samples were sonicated several different times over the course of the experiments. Samples appeared to be stable with up to 15 minutes of sonication exposure. Shorter times were found to lead to incomplete removal of spheres. However, several samples appeared to have spheres remaining after 30 minutes of sonication.

### Example 6

Optical Data Collection and Atomic Force Microscopy Analysis. Transmission and reflection data were collected using a Cary spectrophotometer with an integrating sphere attachment. A packed Teflon™ powder reflectance standard from LabSphere was used as a reference. The instrument baseline was established with the transmission holder empty and the reflectance standard in the reflectance holder.

Fractional nanohole coverage was calculated by counting the number of holes in the AFM image and multiplying by the nominal area of a 92 nm diameter circle and dividing by the total image area. Comparison was made to more complex software package systems for analysis, but for 92 nm structures tip artifacts were found to lead to significant error in measuring an accurate hole coverage.

### Example 7

Electrical characterization. Four point probe sheet resistance measurements were performed at 1 mA, with an in-line 4 point head on nanohole films measuring approximately 1 inch by 1 inch.

### Example 8

Preparation of OPV Cells. Colloidal lithography masks were prepared using latex particles 350 and 92 nm in diameter on glass microscope slides. The latex sphere solution was allowed to assemble on the substrate surface for at least 30 minutes. The films were thermally evaporated with 30 nm of silver and the latex spheres removed by sonication in isopropyl alcohol. FIG. 1 shows an atomic force micrograph of a resulting silver nanohole film with fractional hole coverage of approximately 0.2.

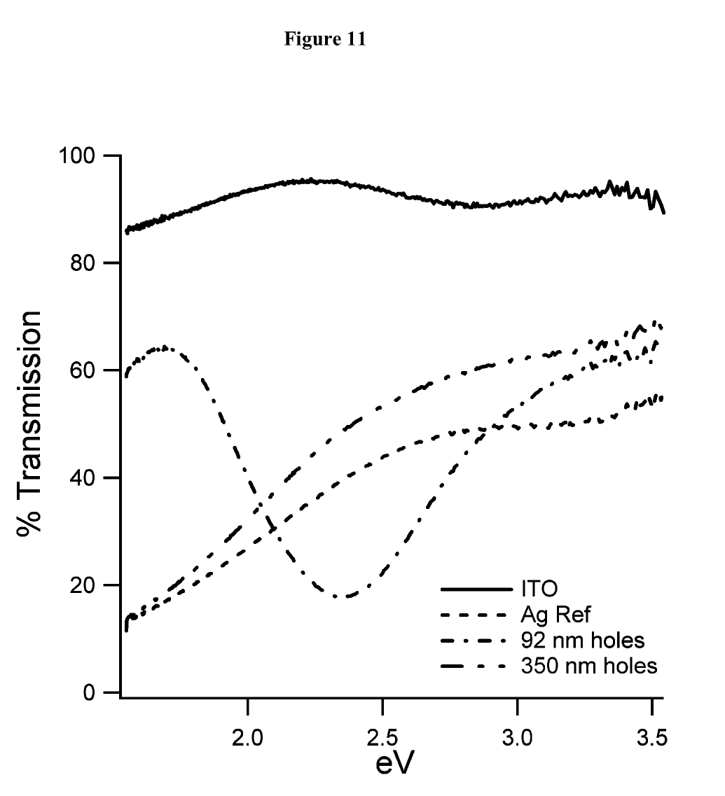

Poly(3,4-ethylenedioxythiophene) poly(styrenesulfonate) (PEDOT:PSS) films were spun at 4000 rpm twice for 60 seconds each and baked at 60° C. for 30 minutes. The uv-visible transmission spectra of nanohole films after the spin coated PEDOT: PSS layer (30 nm) is shown in FIG. 11. The addition of subwavelength holes to the surface of the silver films increased the magnitude of transmission and modulated the spectrum of light that passed through the film. The uncoated silver films with 92 nm holes transmit twice as much light (350-840 nm) as the unpatterned silver films even though the films differ by only about 20% in area, and the 350 nm hole films transmit more light by a factor about 1.3 compared to the unpatterned silver.

The PEDOT:PSS layer was included for two reasons: (1) it assisted the active layer wetting the surface, and (2) it served as an effective spacer layer to prevent chemical interactions between the active layer and the silver. Presumably, the highest electric fields were located in the PEDOT:PSS layer where they cannot be utilized for enhanced absorption in the active layer. Atomic force microscopy analysis revealed that the PEDOT:PSS layer softens the features of the nanoaperture film, leaving shallow depressions (the covered holes) on the surface.

The P3HT:PCBM active-layer solution (20 mg P3HT:20 mg PCBM per 1 mL 1,2-dichlorobenzene kept at 60° C.) was spun onto the substrates at 600 rpm for 60 seconds (150-nm resulting film) and solvent annealed in separate Petri dishes for 1 hour prior to depositing a Ca/Al back electrode (20 nm/100 nm).

### Example 9

OPV Cell Characterization. Table I lists the observed solar-cell device characteristics. Measurements were performed on an XT-10 solar simulator and the light intensity was adjusted to account for solar mismatch. All the samples gave working devices with reasonable solar power conversion efficiencies for the P3HT:PCBM bulk heterojunction system. In general, the silver front electrodes gave lower short-circuit photocurrent (Jsc) than the ITO reference devices, while other device parameters were similar. The reference device shown in Table I had the highest Jsc recorded in this study. More typically, Jsc is in the range of 6-9 mA/cm².

TABLE I

| Test Cell | η (%) | Jsc (mA/cm²) | V_{oc} (mV) | Fill Factor (%) |
|---|---|---|---|---|
| ITO Ref | 3.68 | 10.0 | 605 | 60.7 |
| Ag Ref | 1.03 | 2.67 | 580 | 66.5 |
| 92 nm holes | 1.18 | 3.47 | 581 | 58.8 |
| 350 nm holes | 1.22 | 3.88 | 581 | 53.9 |

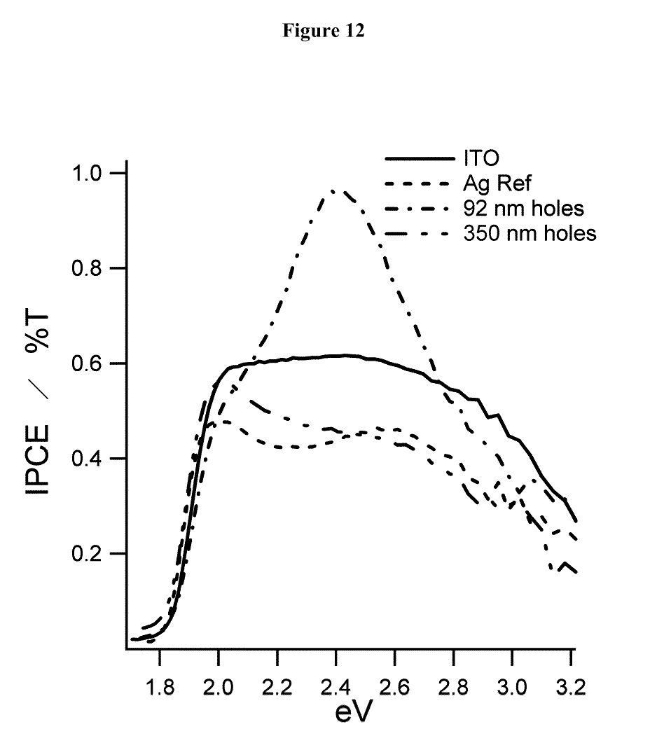

To understand how the nanohole silver films influence Jsc, the incident photon-to-current conversion efficiency (IPCE) spectra were recorded for each of the test cells. An IPCE plot for the test cells prepared in this study is presented in FIG. 12, weighted by the far-field transmission spectra of each respective film measured using a PEDOT:PSS top layer. The presence of the nanoholes in the silver films also boosted the performance of those cells above that of the reference silver film. While the silver reference film and 350-nm hole film demonstrated reduced light utilization compared to the ITO cell, the 92-nm hole film demonstrated a 50% greater conversion of transmitted photons to current compared to the ITO reference cell.

A comparison of the three different silver electrodes suggests one interpretation of the improved photoconversion efficiency observed for the 92 nm nanohole films. Since the 130-nm ITO layer has been replaced by a 30-nm thick silver electrode, it is expected that there will be a change in the optical electric field distribution within the cell. A change in the spatial optical electric field distribution in the cell may explain the reduced photoconversion efficiency and altered lineshape of the weighted IPCE spectra of the silver reference cell as well as the 350-nm nanohole cell.

The IPCE data from the 92-nm nanohole film suggests an interesting phenomenon: the wavelengths that are most highly transmitted by the silver films are utilized with comparable efficiency to the ITO cells, but the wavelengths with the lowest far-field transmission are very efficiently converted to external photocurrent, as is the case at 2.4 eV. A possible explanation is that the surface plasmons best converted to current may be those that remain trapped on the surface and cannot radiate into the far field, thus, extending the interaction time of the photon with the active layer. This interpretation should also result in greater thermalization of the trapped (bound) photons due to the same increased time of the photons being coupled to the surface, hence, the correlation of efficient photocurrent generation with the nanohole film absorbance in the absence of the active layer. Another possible explanation is that the 92-nm hole films create a resonant cavity for 2.1-2.8 eV photons, allowing multiple reflections within the active layer.

The above example demonstrates that nanostructured silver films have been prepared and used as front electrodes in OPV devices, replacing ITO. The silver films with 92 nm holes demonstrated unusual IPCE behavior that may be explained through surface plasmon effects.

It is noted that the examples discussed above are provided for purposes of illustration and is not intended to be limiting. Still other embodiments and modifications are also contemplated.

While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

We claim:

1. A photovoltaic device comprising:
a first electrode comprising a nanohole film;
a second electrode; and
an active layer located between the electrodes.

2. The photovoltaic device of claim 1, wherein the active layer comprises P3HT and PCBM as a bulk heterojunction active layer.

3. The photovoltaic device of claim 1, further comprising a buffer layer comprising a PEDOT-type polymer.

4. The photovoltaic device of claim 1, wherein the nanohole film is a metal film with subwavelength apertures.

5. The photovoltaic device of claim 4, wherein the nanohole film is a silver film with subwavelength apertures.

6. The photovoltaic device of claim 4, wherein the nanohole film subwavelength apertures are less than 300 nm.

7. The photovoltaic device of claim 4, wherein the fractional coverage of the nanoholes across the electrode surface is less than 0.3.

8. A method of producing a nanostructured electrode, comprising:
a) treating a substrate with at least one polyelectrolyte;
b) depositing spheres on the treated substrate;
c) depositing a metal film on the substrate; and
d) removing the spheres from the metal film-coated substrate.

9. The method of claim 8, further comprising a step of washing the substrate prior to depositing the metal film.

10. The method of claim 9, further comprising a step of heating the substrate to reduce aggregation of the spheres.

11. The method of claim 8, wherein the spheres are deposited on the substrate by contacting the substrate with a solution comprising spheres and a salt.

12. The method of claim 11, further comprising a step of altering the salt concentration of the solution comprising the spheres and the salt to change the density of spheres deposited on the substrate.

13. The method of claim 11, wherein the spheres are charged.

14. The method of claim 8, wherein the spheres are removed by sonicating the metal film-coated substrate.

15. The method of claim 8, wherein the metal film is a silver film.

16. A method for determining the optical characteristics of at least one nanohole electrode, comprising:
a) producing at least one nanohole electrode according to the method of claim 8;
b) determining at least one of the transmission or reflection spectrum of the at least one nanohole electrode; and
d) comparing the determined transmission or reflection spectrum with the transmission or reflection spectrum of a reference nanohole electrode.

17. The method of claim 16, wherein the at least one nanohole electrode comprises a different nanohole aperture size than the reference nanohole electrode.

18. The method of claim 16, wherein the at least one nanohole electrode comprises a different nanohole surface coverage than the reference nanohole electrode.

19. The method of claim 16, wherein the at least one nanohole electrode comprises a different nanohole aperture size and nanohole surface coverage than the reference nanohole electrode.

20. A multijunction solar cell comprising more than one electromagnetic radiation absorbing layers and further comprising one or more nanohole films between the electromagnetic radiation absorbing layers.
